(19) United States
(12) Patent Application Publication
(10) Pub. No.: US 2024/0105609 A1
(43) Pub. Date: Mar. 28, 2024

(54) HIGH DENSITY BACKSIDE CAPACITOR AND INDUCTOR

(71) Applicant: International Business Machines Corporation, Armonk, NY (US)

(72) Inventors: Heng Wu, Santa Clara, CA (US); Chen Zhang, Guilderland, NY (US); Min Gyu Sung, Latham, NY (US); Ruilong Xie, Niskayuna, NY (US); Julien Frougier, Albany, NY (US)

(21) Appl. No.: 17/935,602

(22) Filed: Sep. 27, 2022

(51) Int. Cl. H01L 23/528; H01L 21/768; H01L 23/48; H01L 23/522

(52) U.S. Cl. CPC H01L 23/5286; H01L 21/76898; H01L 23/481; H01L 23/5226

(57) ABSTRACT

A semiconductor device a first device located on a frontside of a semiconductor substrate. The semiconductor device further includes an inductor located on a backside of the semiconductor substrate and integrated with a first backside metal (BSM) stack. The semiconductor device further includes a first electrical contact located between the frontside and the backside of the semiconductor substrate. A first end of the first electrical contact is connected to the first BSM stack and a second end of the first electrical contact is connected to a first source/drain region of the first device.

### BACKGROUND

The present disclosure generally relates to fabrication methods and structures for semiconductor devices, and more specifically, to techniques for forming high density backside capacitors and inductors of a semiconductor device.

Advances in semiconductor IC (integrated circuit) chip fabrication and packaging technologies have enabled development of highly integrated semiconductor IC chips and compact chip package structures (or electronic modules). Passive components such as capacitors, resistors and inductors are fundamental circuit components that are commonly used in chip fabrication/packaging designs.

Capacitors are fundamental components for constructing semiconductor integrated circuits including, for example, memory arrays, charge pumps, RC filters, peaking amplifiers and various types of analog integrated circuits. In conventional designs, capacitors are implemented as discrete, off-chip components that are mounted inside a chip package module or on an electrical board (e.g., printed circuit board) on which a chip is mounted. Continuing advances in semiconductor IC chip fabrication and packaging technologies, however, has allowed for the development of high-performance IC chips and chip package structures with increasingly higher levels of integration density, and lower fabrication costs. In this regard, IC chip and package designs utilize on-chip capacitors, for example, to reduce chip package cost and to reduce module size. Moreover, the use of on-chip capacitors, for example, allows for higher performance designs as on-chip capacitors are more effective in reducing noise in power and ground lines when placed closer to the relevant loads.

Inductors are typically used in analog and mixed signal chip designs for constructing various circuits such as voltage controlled oscillators (VCOs), low-noise amplifiers (LNAs), mixers, filters and other integrated circuits. Passive components such as inductors can be fabricated as off-chip or on-chip components. By way of example, inductor components can be fabricated as off-chip components as part of a chip package or disposed at some other location (e.g., printed circuit board). In such off-chip designs, the inductors can be connected to on-chip integrated circuits through C4 contacts or other chip-package contacts such as wire bonds, etc, which can significantly increase the series resistance and degrade circuit performance. Moreover, off-chip designs may not be suitable for high-density integration designs.

Another conventional method for implementing inductors as circuit elements includes constructing inductors as part of the frontside integrated circuit. For instance, on-chip inductors can be fabricated as part of the BEOL (back-end-of-line) wiring structure, which provides interconnects between frontside integrated circuit components. The inductor coils can be patterned in the wiring metallization levels, or patterned in metallization levels that are specifically designed for inductors.

### SUMMARY

According to one embodiment of the present invention, a method includes forming one or more backside metal (BSM) stacks in one or more layers of dielectric material. The one or more BSM stacks are in contact with one or more backside electrical contacts located on a backside of a semiconductor substrate, and the one or more backside electrical contacts are in contact with one or more source/drain regions of a first device located on a front side of the semiconductor substrate. The method further includes forming an inductor that is integrated with a first BSM stack of the one or more BSM stacks. Forming the inductor includes: depositing one or more additional layers of dielectric material on top of the one or more BSM stacks, forming a plurality of inductor via and line openings in the one or more additional layers of dielectric material; and depositing a first conductive metal material in the plurality of inductor via and line openings.

According to another embodiment of the present invention, a semiconductor device includes a first device located on a frontside of a semiconductor substrate. The semiconductor device further includes an inductor located on a backside of the semiconductor substrate and integrated with a first backside metal (BSM) stack. The semiconductor device further includes a first electrical contact located between the frontside and the backside of the semiconductor substrate. A first end of the first electrical contact is connected to the first BSM stack and a second end of the first electrical contact is connected to a first source/drain region of the first device.

According to another embodiment of the present invention, a semiconductor device includes a device located on a frontside of a semiconductor substrate. The semiconductor device further includes a capacitor located on a backside of the semiconductor substrate and integrated with a backside metal (BSM) stack. The semiconductor device further includes a first electrical contact located between the frontside and the backside of the semiconductor substrate. A first end of the first electrical contact is connected to the BSM stack and a second end of the first electrical contact is connected to a source/drain region of the device.

### BRIEF DESCRIPTION OF THE SEVERAL VIEWS OF THE DRAWINGS

FIG. 1 is a top view of a semiconductor device, according to one or more embodiments.

FIG. 2A illustrates a semiconductor substrate, according to one or more embodiments.

FIG. 2B illustrates a silicon-on-insulator (SOI) wafer, according to one or more embodiments.

FIGS. 3A, 3B illustrate arranging a nanosheet stack above, respectively, a dielectric isolation layer and above a buried oxide layer, according to one or more embodiments.

FIGS. 4A, 4B illustrate arranging a plurality of dummy gates above a nanosheet stack, according to one or more embodiments.

FIGS. 5A, 5B illustrate etching through a nanosheet stack to form one or more trenches, according to one or more embodiments.

FIGS. 6A, 6B illustrate forming one or more contact placeholders and one or more source/drain regions, according to one or more embodiments.

FIGS. 7A, 7B illustrate performing one or more additional front end of line (FEOL) processes and one or more back end of line (BEOL) processes, and bonding a carrier wafer to a top surface defined by the one or more BEOL processes, according to one or more embodiments.

FIGS. 8A, 8B illustrate reducing a thickness of a semiconductor substrate, according to one or more embodiments.

FIGS. 9A, 9B illustrate replacing one or more contact placeholders with one or more electrical contacts, according to one or more embodiments.

FIG. 10 illustrates exemplary FEOL fabrication sequences that form one or more backside metal (BSM) stacks of a backside power distribution network (BSPDN), according to one or more embodiments.

FIG. 11 illustrates exemplary FEOL processes that form a backside inductor that is integrated with a first BSM stack of FIG. 10, according to one or more embodiments.

FIG. 12 illustrates exemplary FEOL processes that form a backside capacitor that is integrated with a second BSM stack of FIG. 10 and arranged in parallel with the inductor of FIG. 11, according to one or more embodiments.

FIG. 13 illustrates exemplary FEOL processes that form a backside capacitor and a backside capacitor that are integrated with a first BSM stack of FIG. 10 and arranged in series, according to one or more embodiments.

FIGS. 14A-14C are a method of fabricating a semiconductor device, generally designated 1400A, 1400B, and 1400C, respectively, according to one or more embodiments.

### DETAILED DESCRIPTION

Embodiments of the present invention recognize that depending on the particular application, the use of on-chip capacitors and inductors can be problematic. Capacitors and inductors integrated in current back-end-of-the-line (BEOL) designs occupy a lot of area, making the BEOL wiring very challenging. For example, with high-density chip designs, there can be limited space during the BEOL process for building the integrated capacitors, resulting in practical limitations in integration density. Similarly, the need for inductor wires to be spaced sufficiently apart to minimize self-capacitance results in the fabrication of an inductor structure during the BEOL process with a relatively large footprint.

Accordingly, embodiments of the present invention provide for a semiconductor device having capacitors and inductors located on the backside of the chip by integrating the capacitors and inductors with the back side power delivery network (BSPDN). This ultimately results in a significant decrease in the footprint of on-chip capacitors and inductors without reducing their size, thereby maintaining the necessary performance requirements of these passive elements. Further, depending on the particular circuit needs, capacitors and inductors can be placed both on the frontside and backside of the chip to meet the necessary performance requirements of these passive elements.

Exemplary embodiments now will be described more fully herein with reference to the accompanying drawings, in which exemplary embodiments are shown. In the following detailed description, numerous specific details are set forth in order to provide a thorough understanding of various embodiments of the invention. However, it is to be understood that embodiments of the invention may be practiced without these specific details. As such, this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

As described below, in conjunction with FIGS. 2A,2B-9A,9B and 10-13, embodiments of the present invention include semiconductor passive elements and methods of forming such semiconductor passive elements, and in particular, semiconductor passives elements being integrated with the back side power delivery network (BSPDN) of a semicondcutor device. The methods described below in conjunction with FIGS. 2A,2B-9A,9B and 10-13 may be incorporated into typical semiconductor memory device fabrication processes. As such, when viewed as ordered combinations, FIGS. 2A, 2B-9A,9B and 10-13 illustrate methods for forming semiconductor devices having passive elements (e.g., capacitors and inductors) integrated with the BSPDN of a semiconductor device that maximize passive device performance while reducing and or eliminating the passive device footprint during the BEOL process.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is focused on the distinctive features or elements of various embodiments of the present invention.

As used herein, terms such as “depositing,” “forming,” and the like may refer to the disposition of layers, or portions of materials, in accordance with a given embodiment. Such processes may or may not be different than those used in the standard practice of the art of microcooler device fabrication. Such processes include, but are not limited to, atomic layer deposition (ALD), molecular layer deposition (MLD), chemical vapor deposition (CVD), low-pressure chemical vapor deposition (LPCVD), plasma enhanced chemical vapor deposition (PECVD), limited reaction processing CVD (LRPCVD), ultrahigh vacuum chemical vapor deposition (UHVCVD), metalorganic chemical vapor deposition (MOCVD), physical vapor deposition, sputtering, plating, electroplating, evaporation, ion beam deposition, electron beam deposition, laser assisted deposition, chemical solution deposition, or any combination of those methods.

As used herein, terms, such as “forming,” and the like, may refer to processes that alter the structure and/or composition of one or more layers of material or portions of materials in accordance with a given embodiment. For example, such formation processes may include, but are not limited to, exposure to a specific frequency or range of frequencies of electromagnetic radiation, ion implantation techniques, and/or chemical/mechanical polishing (CMP). As used herein, terms, such as “forming,” and the like, may refer to processes that alter the structure of one or more layers of material, or portions of material(s), by removal of a quantity of material, in accordance with a given embodiment. For example, such formation processes may include, but are not limited to, micromachining, microetching, wet and/or dry etching processes, plasma etching processes, or any of the known etching processes in which material is removed.

Those skilled in the art understand that many different techniques may be used to add, remove, and/or alter various materials, and portions thereof, and that embodiments of the present invention may leverage combinations of such processes to produce the structures disclosed herein without deviating from the scope of the present invention.

The present invention will now be described in detail with reference to the Figures. FIGS. 2A, 2B-9A, 9B and 10-13 include various views depicting illustrative steps of a method for manufacturing semiconductor devices and the resulting semiconductor devices according to select embodiments of the present invention. One having ordinary skill in the art will appreciate that there are many options available for the formation of the structures described herein and that the following discussion does not limit embodiments to only the techniques described herein.

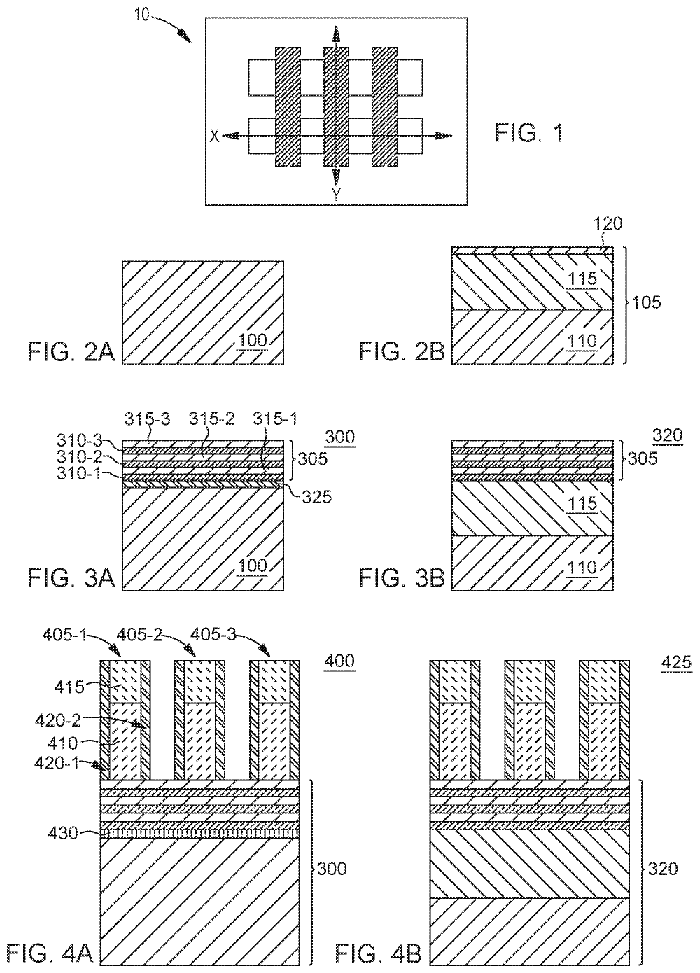

Referring now to FIG. 1, FIG. 1 illustrates a simple diagram of a top view of a semiconductor device 10 according to various embodiments. FIG. 1 is intended only for reference and illustrates a top-down view of locations and relative orientations of the nanosheets and future gates during fabrication. For simplicity and ease of understanding, FIG. 1 omits some elements and/or layers so as to not obscure the figure. Subsequent figures (i.e., FIGS. 2A,2B-9A,9B and 10-13) depict a cross-sectional view of the semiconductor device 10 of FIG. 1 taken along line X.

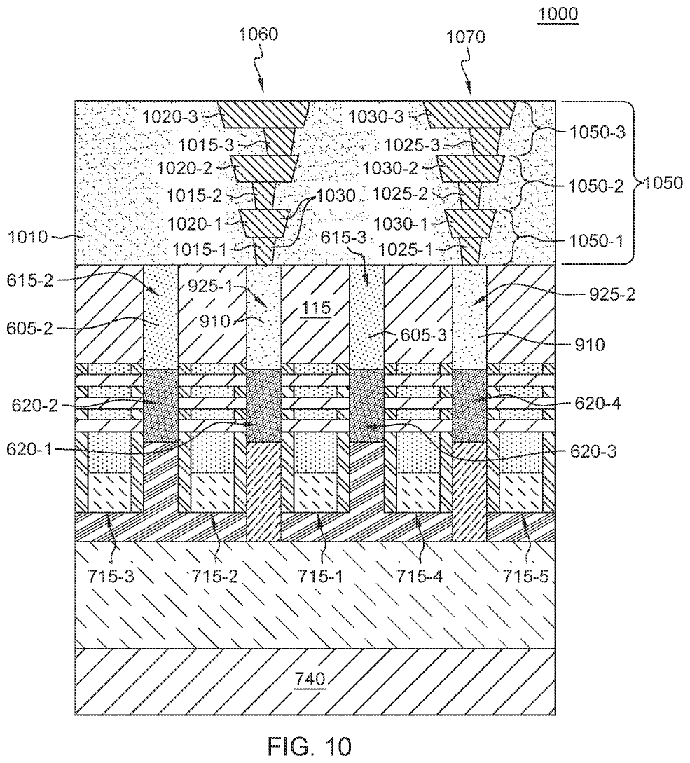

FIGS. 2A,2B-9A,9B illustrate exemplary fabrication sequences that form backside electrical contacts to source and drain regions of a semiconductor device using contact placeholders. More specifically, FIGS. 2A-9A illustrate various operations of a first fabrication sequence beginning with a silicon substrate 100, while FIGS. 2B-9B illustrate various operations of a second fabrication sequence beginning with a silicon-on-insulator (SOI) wafer 105. FIGS. 10-13 continue the fabrication sequence of FIGS. 2B-9B, but the illustrated operations of FIG. 10-13 will be understood to be similarly applicable to the fabrication sequence of FIGS. 2A-9A. Moreover, any operations, features, benefits, etc. that are described with respect to a particular fabrication sequence will be understood to be similarly applicable to the other fabrication sequence, unless otherwise explicitly noted.

In some embodiments, the starting substrate of FIG. 2A includes the silicon substrate 100, although other semiconductor materials are contemplated. In another embodiment, the starting substrate of FIG. 2B includes a SOI wafer 105. The SOI wafer 105 includes a silicon substrate 110, a buried oxide (BOX) layer 115 above the silicon substrate 110, and a surface semiconductor layer 120.

The surface semicondcutor layer 120 may have a thickness in a range between less than 100 nanometers (nm) to greater than a micron. In some embodiments, the surface semiconductor layer 120 has a thickness between 10 and 300 nanometers (nm). A thickness of the BOX layer 115 may vary depending on the specific application. In some embodiments, the BOX layer 115 has a thickness between 30 and 200 nm. The thickness of the silicon substrate 110 may vary widely depending on the specific application. For example, the silicon substrate 110 may have a thickness similar to that of a typical semiconductor wafer (e.g., 100-700 microns), or the silicon substrate 110 may be thinned and mounted on another substrate.

In assembly 300 of FIG. 3A, a nanosheet stack 305 is arranged above the sacrificial isolation layer 325. In assembly 320 of FIG. 3B, the nanosheet stack 305 is arranged above the BOX layer 115. The nanosheet stack 305 comprises an alternating arrangement of Si layers 315-1, 315-2, 315-3 and SiGe layers 310-1, 310-2, 310-3. Although three (3) Si layers and three (3) SiGe layers are shown, other numbers of Si layers and SiGe layers are contemplated. The nanosheet stack 305 may be further processed to define NFET region(s) and PFET region(s) of the semiconductor device.

The Si layers 315-1, 315-2, 315-3 and SiGe layers 310-1, 310-2, 310-3 may be epitaxially grown above the sacrificial isolation layer 325 (or above the BOX layer 115). As used herein, the term “epitaxially grown” means the growth of a semiconductor (crystalline) material on a deposition surface of another semiconductor (crystalline) material, in which the semiconductor material being grown (crystalline overlayer) has substantially the same crystalline characteristics as the semiconductor material of the deposition surface (seed material). In an epitaxial growth process, chemical reactants provided by source gases, as well as system parameters, are controlled to cause the depositing atoms to arrive at the deposition surface with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface. For example, an epitaxially grown semiconductor material deposited on a {100} orientated crystalline surface will take on a {100} orientation. In some embodiments, epitaxial growth processes are selective to forming on semiconductor surfaces, and generally do not deposit material on exposed surfaces such as silicon dioxide or silicon nitride surfaces.

The SiGe layers 310-1, 310-2, 310-3 may have any suitable atomic percentage of Ge. For convenience and ease of understanding, SiGe layers having a relatively lesser atomic percentage of Ge (such as the SiGe layers 310-1, 310-2, 310-3) will be referred as SiGe(x). In some embodiments, the SiGe(x) layers have a Ge concentration (x) from 5 atomic percent to 50 atomic percent. In some embodiments, the SiGe(x) layers have a Ge concentration from 10 atomic percent to 40 atomic percent. In some embodiments, the SiGe(x) layers have a Ge concentration from 20 atomic percent to 30 atomic percent.

In some embodiments, the layers of the nanosheet stack 305 have a thickness less than or comparable to that of the sacrificial isolation layer 325. In some embodiments, the Si layers 315-1, 315-2, 315-3 have a thickness of 4 to 10 nm, and the SiGe(x) layers 310-1, 310-2, 310-3 have a thickness of 8 to 15 nm. In one non-limiting example, the sacrificial isolation layer 325 has a thickness of about 10 nm, the Si layers 315-1, 315-2, 315-3 have a thickness of about 6 nm, and the SiGe(x) layers 310-1, 310-2, 310-3 have a thickness of about 10 nm.

The sacrificial isolation layer 325 may be an SiGe layer with a relatively greater Ge concentration than the SiGe(x) layers 310-1, 310-2, 310-3. In some embodiments, the sacrificial isolation layer 325 may be a SiGe(x+25) layer having a Ge concentration that is at least 25 atomic percent greater than the SiGe(x) layers. In some embodiments, the nanosheet stack 305 may include one or more SiGe(x+25) layers in addition to the SiGe(x) layers. The greater Ge concentration in the SiGe(x+25) layers provides an etch selectivity greater than or equal to 30:1 relative to the lesser Ge concentration SiGe(x) layers. For example, the SiGe(x+25) layers may be selectively removed using HCl vapor etch chemistry.

In some embodiments, the nanosheet stack 305 is formed by growing epitaxy layers above the silicon substrate 100 (FIG. 3A) as follows: a first SiGe layer having a high Ge concentration (e.g., greater than 50%) as a sacrificial isolation layer, and subsequent alternating layers of SiGe (e.g., 20-35% Ge) and Si above the sacrificial isolation layer.

In some embodiments, the nanosheet stack 305 is formed (FIG. 3B) as follows. The surface layer 120 of the SOI wafer 105 is thinned to have a thickness of approximately 5 to 10 nm. A layer of SiGe (30-60% Ge) is grown above the thinned surface layer 120. One example thickness of the SiGe layer is approximately 10 nm. An oxidation process is performed to intermix the Si of the surface layer 120 with the SiGe layer to form a lower-concentration SiGe layer (20-40% Ge) with SiO₂ formed above. The SiO₂ may be removed using dilute hydrofluoric acid (DHF), and subsequent alternating layers of Si and SiGe (e.g., 20-35% Ge) may be grown above the lower-concentration SiGe layer. The nanosheet stack 305 is further patterned so an unwanted portion of the nanosheet stack 305 is removed to define nanosheet fins, and shallow trench isolations (STI) are formed between the neighboring nanosheet fins (not shown in X-cut).

In assembly 400 of FIG. 4A, and in assembly 425 of FIG. 4B, a plurality of dummy gates 405-1, 405-2, 405-3 are arranged above the nanosheet stack 305. Although three dummy gates are depicted, embodiments of the present invention are not limited to any particular number of dummy gates formed. In some embodiments, the dummy gates 405-1, 405-2, 405-3 are formed by depositing dummy gate material 410, such as a thin layer of SiO₂ followed by amorphous Si, on the relevant layer. The dummy gate material 410 may be planarized to a desired level. A hard mask gate cap 415 is formed on the dummy gate material 410. The hard mask gate cap 415 may be a nitride, oxide, and/or a combination nitride and oxide multi-layer. Although not shown, in some embodiments, a pad oxide may be deposited on the dummy gate material 410 prior to forming the hard mask gate cap 415. In some embodiments, the dummy gates 405-1, 405-2, 405-3 are formed by patterning the hard mask gate cap 415, and then using the patterned hard mask gate cap 415 to etch the dummy gate material 410 into the dummy gates 405-1, 405-2, 405-3. After that, to form the dielectric isolation layer 430, the sacrificial isolation layer 325 may be selectively etched, using HCl or ClF3, without etching the alternating layers of SiGe and Si. Although the alternating layers would appear as floating in cross-sectional views, it is noted that the layers (including the nanosheet stack 305) are anchored to the dummy gates 405-1, 405-2, 405-3 as depicted in FIG. 4A.

After that, conformal deposition of a low-K spacer material forms the dielectric isolation layer 430 and gate spacers 420-1, 420-2. Some examples of the low-K spacer material include silicon boron carbide nitride (SiBCN), SiO, SiOC, SiOCN, and so forth. Thus, the dielectric isolation layer 430 in FIGS. 4A, etc. provides an SOI-like full isolation without requiring use of an SOI substrate as in FIGS. 3B, 4B, etc. One exemplary method of forming the dielectric isolation layer 430 is described in U.S. Pat. No. 10,903,315, which is herein incorporated by reference in its entirety. Each of the dummy gates 405-1, 405-2 has gate spacers 420-1, 420-2 formed along sidewalls defined by the dummy gate material 410 and the hard mask gate cap 415. In one embodiment, the gate spacers 420-1, 420-2 are formed by a conformal deposition of a dielectric material (e.g., silicon oxide, silicon nitride, silicon oxynitride, SiBCN, SiOCN, SiOC, or any suitable combination of those materials) followed by a directional etch (e.g., reactive ion etch (RIE)).

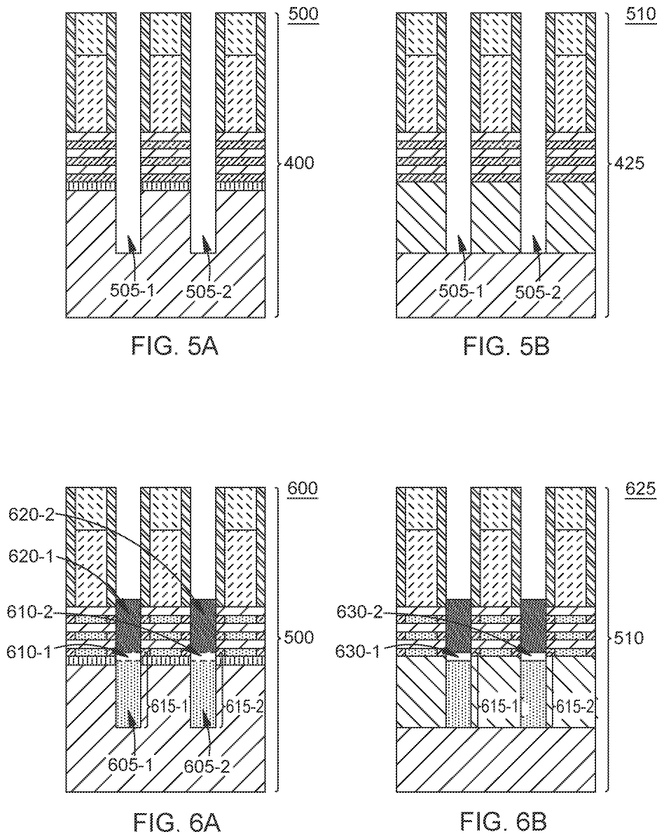

In assembly 500 of FIG. 5A, one or more etch processes are performed to etch through the nanosheet stack 305, through the dielectric isolation layer 430, and partly through the semiconductor substrate 100 to form trench 505-1 between the dummy gates 405-1, 405-2 and trench 505-2 between the dummy gates 405-2, 405-3.

In assembly 510 of FIG. 5B, one or more etch processes are performed to etch through the nanosheet stack 305 and at least partly through the BOX layer 115. In some embodiments, the etch extends partly through the BOX layer 115. In other embodiments, the etch extends through the BOX layer 115 and partly through the silicon substrate 110. As will be discussed below, the depth of the etch may depend on the sacrificial material selected to operate as a contact placeholder.

FIGS. 6A, 6B illustrate forming inner spacers to seal the sacrificial SiGe layers 310-1, 310-2, and 310-3, followed by forming one or more contact placeholders 615-1, 615-2, and one or more source/drain regions 620-1, 620-2. In assembly 600 of FIG. 6A, and in assembly 625 of FIG. 6B, the sacrificial SiGe(x) layers 310-1, 310-2 and 310-3 are selectively etched such that cavities are formed under the spacer region. After that, an inner spacer is formed by a conformal dielectric liner deposition followed by isotropic dielectric liner etch back. The material of the inner spacer could be the same or similar to the gate spacer material 420-1 and 420-2. In assembly 600 of FIG. 6A, and in assembly 625 of FIG. 6B, a sacrificial material 605-1, 605-2 is then formed in the trenches 505-1, 505-2. The sacrificial material 605-1, 605-2, forms some or all of the contact placeholders 615-1, 615-2, which may be used to form one or more self-aligned electrical contacts to the source/drain regions 620-1, 620-2 in subsequent operations.

In some embodiments, the sacrificial material 605-1, 605-2 includes a dielectric material, such as silicon dioxide, SiC, SiOC, AlOx, etc. In this case, the sacrificial material 605-1, 605-2, extends through the regions 610-1, 610-2 and the semiconductor material used to form the source/drain regions 620-1, 620-2 is deposited above and contacts the sacrificial material 605-1, 605-2. In some embodiments, the semiconductor material of the source/drain regions 620-1, 620-2 includes SiGe having a Ge concentration greater than that of the SiGe(x), such as SiGe(x+25), although other types of semiconductor materials are also contemplated.

In some embodiments, the sacrificial material 605-1, 605-2 includes a semiconductor material, such as SiGe(x+25), and a different semiconductor material is deposited in the regions 610-1, 610-2 to form semiconductor buffers 630-1, 630-2 that separate the sacrificial material 605-1, 605-2 from the semiconductor material of the source/drain regions 620-1, 620-2 when deposited. In this case, the source/drain regions 620-1, 620-2 contact the semiconductor buffers 630-1, 630-2. In some embodiments, the semiconductor buffers 630-1, 630-2 are formed of Si, although other types of semiconductor materials are also contemplated.

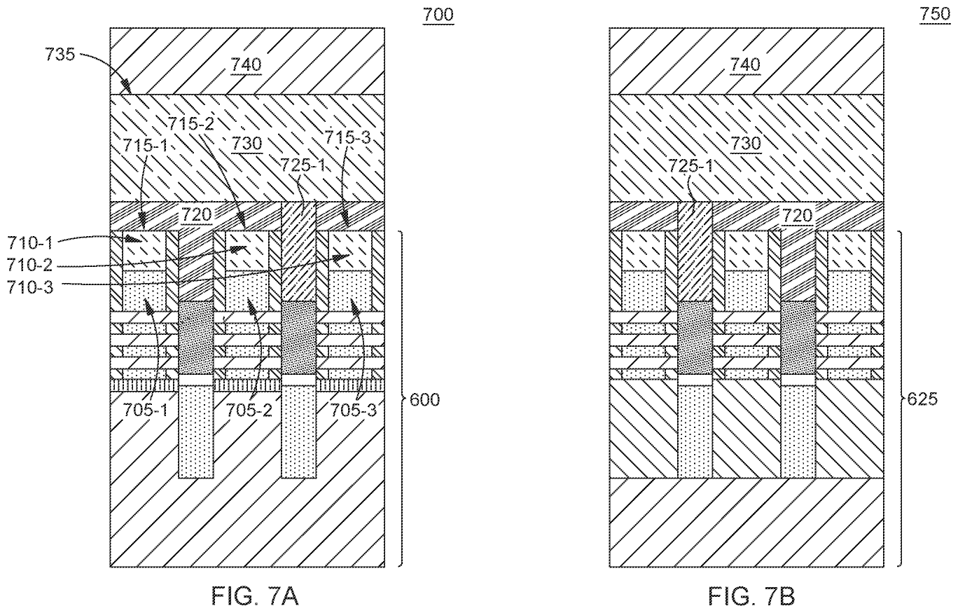

FIGS. 7A, 7B illustrate performing one or more additional front end of line (FEOL) processes and one or more back end of line (BEOL) processes, and bonding a carrier wafer 740 to a top surface 735 defined by the one or more BEOL processes. In assembly 700 of FIG. 7A, and assembly 750 of FIG. 7B, the one or more FEOL processes includes forming an interlayer dielectric (ILD) layer 720 above the source/drain regions 620-1, 620-2, removing the hard mask gate cap 415 and the dummy gate material 410 of the dummy gates 405-1, 405-2, 405-3 (depicted in FIGS. 4A and 4B), and forming gates 715-1, 715-2, 715-3 in the openings formed between the gate spacers 420-1, 420-2. In some embodiments, forming the gates 715-1, 715-2, 715-3 includes filling the openings with one or more gate materials 705-1, 705-2, 705-3. The one or more FEOL processes may further comprise arranging gate caps 710-1, 710-2, 710-3 above the gate materials 705-1, 705-2, 705-3.

In some embodiments, the one or more gate materials 705-1, 705-2, 705-3 include a gate dielectric layer and a conductive gate metal. For example, the one or more gate materials 705-1, 705-2, 705-3 may form a high-k/metal gate. In some embodiments, the gate dielectric layer comprises a high-dielectric constant (high-k) material, such as hafnium oxide (HfO₂), that is conformally deposited into the opening formed between the gate spacers 420-1, 420-2. Other types of high-k materials are also contemplated, and in some cases may include dopants. The high-k material thus conforms to the profile of the opening and the channel regions of the nanosheet stack 305 (depicted in FIGS. 4A and 4B). The gate dielectric layer can be deposited by chemical vapor deposition (CVD), atomic layer deposition (ALD), or any other suitable technique. The gate dielectric layer may have a thickness in the non-limiting range of about 0.7 nm to about 3 nm.

The conductive gate metal of the one or more gate materials 705-1, 705-2, 705-3 may be formed by depositing an electrically conductive material into the opening formed between the gate spacers 420-1, 420-2. The conductive gate metal may be formed of any suitable conducting material, such as a semiconductor material, a metal, a conductive metallic compound, carbon nanotubes, conductive carbon, graphene, or any suitable combinations thereof. In some cases, the conductive material may further include dopants. Conductive metal comprises work function metals such as TiN, TiAlC, TiC, etc, and optionally low resistance capping metals, such as W, Al, etc.

In some embodiments, the conductive gate metals of the gates 715-1, 715-2, 715-3 are partially recessed to form a cavity, which is then backfilled with dielectric material, such as silicon nitride (SiN), to form the gate caps 710-1, 710-2, 710-3. In alternate embodiments, the conductive gate metals extend to a top of the gate spacers 420-1, 420-2, and may be formed using a chemical-mechanical planarization (CMP) process to remove excess material from the upper surface. Accordingly, the conductive gate metal surrounds the entire circumference of the active layers of the nanosheet stack 305 (depicted in FIGS. 4A and 4B).

In some embodiments, the one or more FEOL processes include depositing a dielectric material after forming the source/drain regions 620-1, 620-2, and before removing the hard mask gate cap 415 and the dummy gate material 410 of the dummy gates 405-1, 405-2, 405-3. In some embodiments, the one or more FEOL processes comprise depositing the ILD layer 720 above the gates 715-1, 715-2, 715-3 and forming one or more electrical contacts, such as electrical contact 725-1 (that is, an electrical contact located on a frontside of semiconductor 100, 110) through the ILD layer 720 to the source/drain region 620-2. The ILD layer 720 may be formed of any suitable dielectric material, such as silicon dioxide.

In some embodiments, the one or more BEOL processes include forming one or more layers 730 above the ILD layer 720. In some embodiments, the one or more layers 730 include a plurality of metal via and line layers separated by a plurality of dielectric layers. The one or more layers 730 provide interconnection between various components of the semiconductor device, e.g., connecting to the source/drain region 620-2 through the electrical contact 725-1. In some embodiments, a carrier wafer 740 is bonded to a top surface 735 of the one or more layers 730 to accommodate further handling and processing of the semiconductor device. Any suitable materials and bonding techniques for the carrier wafer 740 are contemplated and will be understood by the person of ordinary skill in the art.

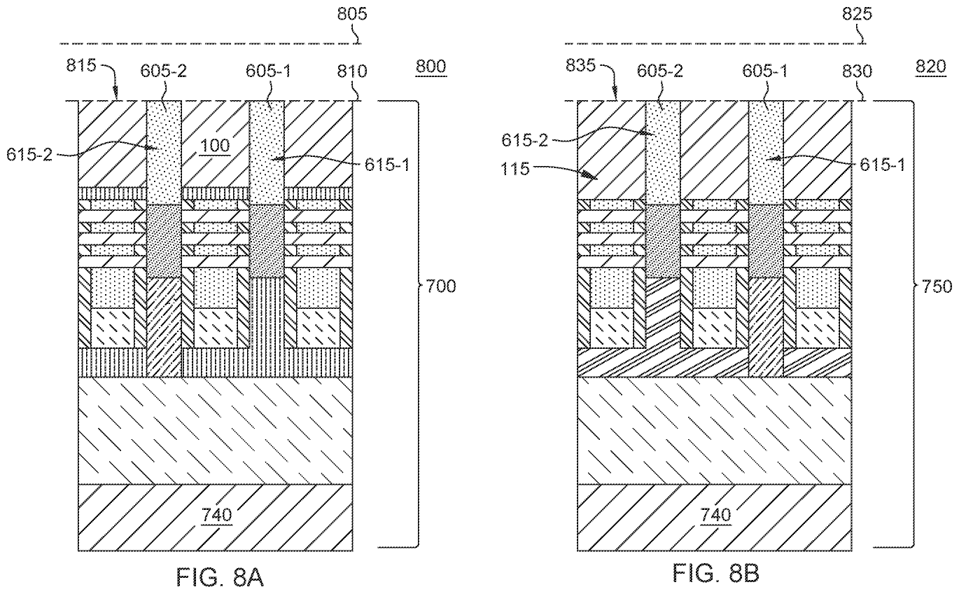

FIGS. 8A, 8B illustrate reducing a thickness of the semiconductor substrate 100. In assemblies 800, 820, the assemblies 700, 750 have been inverted using the carrier wafer 740. In semiconductor based implementations such as assembly 800 of FIG. 8A, after the FEOL process(es) and BEOL process(es) and bonding the carrier wafer 740, the semiconductor substrate 100 is reduced, using any suitable techniques, from a first thickness 805 to a second thickness 810 to define a bottom surface 815 of the semiconductor substrate 100. For example, the semiconductor substrate 100 may be thinned using a combination of a backside grinding process, CMP process, or a wet/dry etch.

In SOI-based implementations such as assembly 820 of FIG. 8B, after the FEOL process(es) and BEOL process(es) and bonding the carrier wafer 740, the semiconductor substrate 110 is reduced from a first thickness 825 to a second thickness 830 to define a bottom surface 835 of the BOX layer 115 (e.g., entirely removing the semiconductor substrate 110).

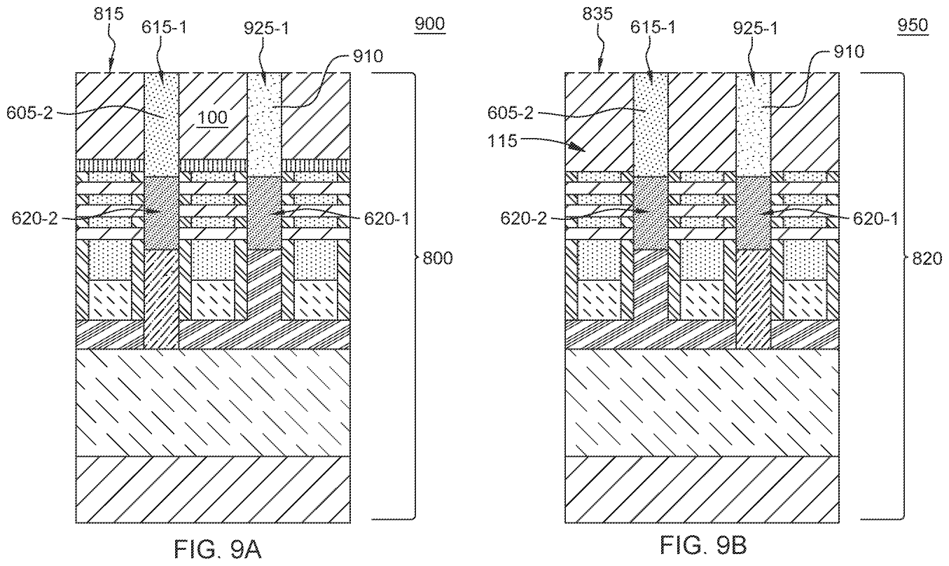

FIGS. 9A, 9B illustrate replacing the contact placeholder 615-2 with an electrical contact 925-1 (that is, an electrical contact that is located on the backside of semiconductor substrate 110, 110) that is self-aligned to the source/drain region 620-1. Depending on the particular requirements of the semiconductor device, any number of the contact placeholders may be replaced with electrical contacts that are self-aligned to the source/drain regions. In some embodiments, and as depicted in FIGS. 9A, 9B, any contact placeholders that are not replaced with backside electrical contacts may remain in the completed semiconductor device. For example, contact placeholder 615-2 formed from sacrificial material 605-2 has not been replaced with an electrical contact. In other embodiments, any contact placeholders that are not replaced with backside electrical contacts may be replaced with at least one of an ILD material or a BOX material.

In assembly 900 of FIG. 9A, the sacrificial material 605-1 (depicted in FIG. 8A) is selectively etched (e.g., SiGe) relative to the semicondcutor substrate 100 to define openings (not depicted) corresponding to the removed sacrificial material 605-1. The opening is filled with a metal contact material 910 (e.g., via atomic layer deposition, chemical vapor deposition, plating, electroplating, or any other suitable deposition techniques) until the metal contact material 910 is at least substantially coplanar with the bottom surface 815 of semiconductor substate 100. A planarization process, such as, for example, chemical mechanical planarization or polishing (CMP) and/or grinding may be performed to remove any metal contact material 910 (i.e., “overburden material”) formed outside of the opening to form electrical contact 925-1.

In SOI-based implementations such as assembly 950 of FIG. 9B, the sacrificial material 605-1 may be selectively etched relative to the BOX layer 115 to form an opening (not depicted) corresponding to the removed sacrificial material 605-1. In some embodiments, the semiconductor buffer 630-1 may also be removed in addition to the sacrificial material 605-1. The opening is filled with the metal contact material 910 (e.g., via atomic layer deposition, chemical vapor deposition, plating, electroplating, or any other suitable deposition techniques) until the metal contact material 910 is at least substantially coplanar with the bottom surface 835 of the BOX layer 115. A planarization process, such as, for example, chemical mechanical planarization or polishing (CMP) and/or grinding may be performed to remove any of the metal contact material 910 (i.e., “overburden material”) formed outside of the opening.

In either the assembly of 900 or 950, the metal contact material 910 may be a metal or metal alloy including, but not limited to, copper (Cu), aluminum (Al), ruthenium (Ru), rhodium (Rh), iridium (Jr), tungsten (W), molybdenum (Mo), nickel (Ni), or an alloy thereof, such as, for example, a Cu—Al alloy.

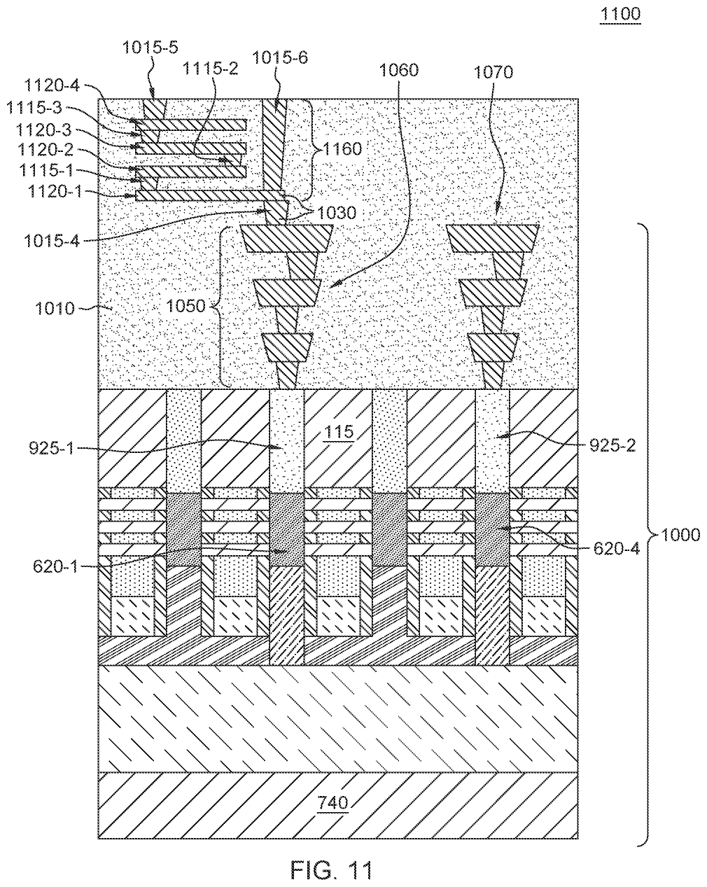

FIG. 10 illustrates exemplary FEOL fabrication sequences that form the backside metal (BSM) layers 1050 of the backside power distribution network (BSPDN) of the semiconductor device. The BSM layers 1050 include a plurality of via and line layers separated by a plurality of layers of an interlayer dielectric (ILD) material 1010. While the operations of FIG. 10 (and the operations of subsequent FIGS. 11-13) are specifically performed with reference to the fabrication sequence of FIGS. 2B-9B for simplicity sake, the operations of FIG. 10 (and the subsequent operations of FIGS. 11-13) are also applicable to the fabrication sequence of FIGS. 2A-9A.

As depicted in FIG. 10, additional gates 715-4, 715-5, an additional contact placeholder 615-3, and an additional electrical contact 925-2 (that is, an electrical contact that is located on the backside of semicondcutor substrate 100, 110) have been formed using the same processes and materials as described above with reference to FIGS. 4A,4B-9A,B.

In the exemplary fabrication process discussed below, a first BSM layer 1050-1 is formed using a standard via first dual damascene process, wherein the via openings and line openings (not depicted) of vias 1015-1, 1025-1 and lines 1020-1, 1030-1 to be formed are sequentially etched in a layer of ILD material 1010 in alignment with the electrical contacts 925-1, 925-2, and wherein the via openings and the line openings are filled with a conductive metal material 1030 in a single metal deposition process (e.g., copper electroplating) to form the first backside metal layer 1050-1. However, it is to be understood that other standard processes such as single damascene, a standard line first dual damascene process, or subtractive etch techniques may be used to form the first backside metal layer 1050-1.

The layer of ILD material 1010 is deposited onto the surface of assembly 950 of FIG. 9B, and the via openings are formed following the patterning of the layer of ILD material 1010 using a dual damascene process. For example, a hard mask layer (not depicted) is formed by depositing a hard mask material (e.g., silicon nitride, titanium nitride, tantalum nitride, or any suitable metal-containing material) onto the surface of the layer of ILD material 1010. The hard mask layer can be formed utilizing a deposition process including, but not limited to, CVD, PECVD, ALD, physical vapor deposition (PVD) or sputtering.

A photoresist material (not depicted) is then deposited onto the surface of the hard mask layer. The photoresist material can be applied by any suitable techniques, including, but not limited to, coating or spin-on techniques. A photomask (not depicted) patterned with shapes defining the via openings to be formed is placed over the photoresist material, and the photomask pattern is transferred to the photoresist material using a lithographic process, which creates recesses in the uncovered regions of the photoresist material. The resulting patterned photoresist material is subsequently used to create the same pattern in the hard mask layer. Dry etch techniques (for example, an anisotropic etch process, such as reactive ion etch) may be employed to selectively remove portions of the hard mask layer to form the patterned hard mask. After formation of patterned hard mask, the photoresist material may be stripped from the patterned hard mask by ashing or other suitable processes. The resulting structure may be subjected to a wet clean.

The resulting patterned hard mask, which acts as an etch mask, is formed such that the portions of the underlying layer of ILD material 1010 corresponding to the via openings to be formed are left exposed, while the remaining portions of the underlying structure of the layer of ILD material 1010 is protected by the patterned hard mask. During patterning of the layer of ILD material 1010 using the patterned hard mask, the physically exposed portions of the layer of ILD material 1010 are removed by an anisotropic etching process such as, for example, reactive ion etching (RIE), ion beam etching (IBE), chemical wet etching, or a combination of IBE and chemical wet etching. The etch removes the exposed portions of the layer of ILD material 1010 that are not protected by the patterned hard mask to form the via openings. The depth(s) of the via openings can be controlled using a timed etching process.

After forming the via openings, another patterned hard mask (not depicted) is formed on the exposed surface of the layer of ILD material 1010. The patterned hard mask may be formed using the same processes and materials for forming the via openings as described above. The resulting patterned hard mask, which acts as an etch mask, is formed such that the portion of the underlying structure of the layer of ILD material 1010 corresponding to the line openings to be formed is left exposed, while the remaining portions of the underlying structure of the layer of ILD material 1010 is protected by the patterned hard mask. The portions of the layer of ILD material 1010 left uncovered by the patterned hard mask are removed by an anisotropic etching process.

A metal liner (not depicted) is conformally deposited on the exposed surfaces of the patterned layer of ILD material 1010. The metal liner may include one or more thin layers of material such as, for example, tantalum (Ta), tantalum nitride (TaN), titanium nitride (TiN), cobalt (Co), ruthenium (Ru), tungsten (W), tungsten nitride (WN), titanium-tungsten (TiW), tungsten nitride (WN) manganese (Mn), manganese nitride (MnN) or other liner materials (or combinations of liner materials) such as RuTaN, Ta/TaN, CoWP, NiMoP, or NiMoB which are suitable for the given application. The thin metal liner serves as a barrier diffusion layer and adhesion layer. A conformal layer of the metal liner may be deposited using known techniques including, but not limited to, chemical vapor deposition (CVD), plasma enhanced chemical vapor deposition (PECVD), atomic layer deposition (ALD), physical vapor deposition (PVD), sputtering, chemical solution deposition or plating. The thickness of the metal liner may vary depending on the deposition process used, as well as the material employed. In some embodiments, the metal liner may have a thickness from 2 nm to 50 nm. However, other thicknesses that are less than 2 nm, or greater than 50 nm can also be employed in embodiments of the present invention, as long as the metal liner does not entirely fill the via and line openings.

In some embodiments, an optional plating seed layer (not depicted) can be formed on the metal liner as well. The optional plating seed layer is employed to selectively promote subsequent electroplating of a pre-selected conductive metal or metal alloy. The optional plating seed layer may be composed of Cu, a Cu alloy, Jr, an Jr alloy, Ru, a Ru alloy (e.g., TaRu alloy) or any other suitable noble metal or noble metal alloy having a low metal-plating overpotential. Typically, a Cu or Cu alloy plating seed layer is employed when a Cu metal is to be subsequently formed within the via and line openings. The optional plating seed layer can be formed by a conventional deposition process including, for example, CVD, PECVD, ALD, or PVD. The thickness of the optional plating seed layer may vary depending on the material of the optional plating seed layer, as well as the technique used in forming the same. Typically, the optional plating seed layer may have a thickness from 2 nm to 80 nm. However, other thicknesses that are less than 2 nm, or greater than 80 nm can also be employed in embodiments of the present invention, as long as the optional plating seed layer does not entirely fill the via and line openings.

The via and line openings are filled with the conductive metal material 1030 until the conductive metal material 1030 is at least substantially coplanar with the bottom surface of the layer of ILD material 1010. In an embodiment, the conductive metal material 1030 may be a metal or metal alloy including, but not limited to, copper (Cu), aluminum (Al), ruthenium (Ru), rhodium (Rh), iridium (Jr), tungsten (W), molybdenum (Mo), nickel (Ni), or an alloy thereof, such as, for example, a Cu—Al alloy. In those embodiments in which a thin conformal copper (Cu) seed layer (not depicted) is deposited over the surface of the metal liner using, for example, PVD, the metal material 1030 is subsequently formed by electroplating of Cu to fill the via and line openings. In those embodiments in which the metal liner is not used, the conductive metal material 1030 is deposited directly onto the exposed surfaces of the patterned layer of ILD material 1010. The conductive metal material 1030 can be formed utilizing a deposition process such as, for example, CVD, PECVD, sputtering, chemical solution deposition or plating.

In an embodiment, the conductive metal material 1030 is formed within and filling the via and line openings by depositing the conductive metal material 1030, followed by a thermal annealing. For example, the thermal annealing can be a furnace anneal, rapid thermal anneal, flash anneal, or laser anneal. In an embodiment, for furnace anneal and rapid thermal anneal, the annealing temperature can range from 150° C. to 450° C. for furnace anneal and rapid thermal anneal and the anneal duration can range from 10 minutes to one hour. In an embodiment, for flash anneal/laser anneal, the annealing temperature can be higher (e.g., from 450° C. to 1000° C.), but the anneal duration is much shorter (e.g., ranging from 100 nanoseconds to 100 milliseconds).

A planarization process such as, for example, chemical mechanical planarization or polishing (CMP) and/or grinding, may subsequently be performed to remove portions of the metal liner, the optional plating seed layer (not depicted), and the conductive metal material 1030 (collectively referred to as “overburden material”) that is present below the bottom surface of the layer of ILD material 1010 to form the vias 1015-1, 1025-1 and the lines 1020-1, 1030-1, respectively. The planarization stops at the bottom surface of the layer of ILD material 1010, such that the metal liner, the optional plating seed layer (not depicted), and the conductive metal material 1030 are substantially coplanar with the bottom surface of the layer of ILD material 1010.

For simplicity sake, only the formation of the first BSM layer 1050-1 has been described. However, it should be understood that the formation of any number of additional BSM layers (e.g., the BSM layers 1050-2, 1050-3, including the vias 1015-2, 1015,3, and 1025-2, 1025-3, and the lines 1020-2, 1020-3 and 1030-2, 1030-3) as depicted in FIG. 10 may be formed utilizing the same processes and materials used to form the vias 1015-1, 1025-1 and the lines 1020-1, 1030-1 as described above.

As further depicted in FIG. 10, the BSM layers 1050 form a first backside metal stack 1060 and a second backside metal stack 1070. The backside metal stacks 1060, 1070 provide interconnection between various components of the semiconductor device, e.g., connecting to the source/drain region 620-1 through the electrical contact 925-1, and connecting to the source/drain region 620-4 through the electrical contract 925-2. Although only two backside metal stacks are depicted in FIG. 10, embodiments of the present invention may be practiced having any number of backside metal stacks connected to source/drain regions of the semiconductor device through electrical contacts.

FIG. 11 illustrates exemplary FEOL processes for the formation of a backside inductor 1160. In the exemplary FEOL fabrication processes discussed below, a first backside inductor layer 1160 is formed using a standard via first dual damascene process, wherein the via opening and line opening (not depicted) of via 1015-4 (that is, a backside via) and line 1120-1 (that is, a backside line) to be formed are sequentially etched in a layer of the ILD material 1010 in alignment with the electrical contact 925-1, and wherein the via opening and the line opening are filled with the conductive metal material 1030 in a single metal deposition process (e.g., copper electroplating. However, it is to be understood that other standard processes such as single damascene, a standard line first dual damascene process, or subtractive etch techniques may be used.

In assembly 1100 of FIG. 11, the layer of ILD material 1010 is formed on the assembly 1000 of FIG. 10, and the via opening and the line opening (not depicted) are formed in the layer of ILD material 1010. A first patterned hard mask (not depicted) is formed on the exposed surface of the layer of ILD material 1010 such that the portion of the underlying layer of ILD material 1010 corresponding to the via opening to be formed is left exposed, while the remaining portions of the underlying structure of the layer of ILD material 1010 are protected by the patterned hard mask. The portion of the layer of ILD material 1010 left uncovered by the patterned hard mask is removed using an anisotropic etching process.

After the via opening is formed, another patterned hard mask (not depicted) is formed on the exposed surface of the layer of ILD material 1010 such that the portion of the underlying layer of ILD material 1010 corresponding to the line opening to be formed is left exposed, while the remaining portions of the underlying layer of the ILD material 1010 are protected by the patterned hard mask. The portions of the layer of the ILD material 1010 left uncovered by the patterned hard mask is similarly removed by an anisotropic etching process.

A metal liner (not depicted) is conformally deposited on the exposed surfaces of the patterned layer of ILD material 1010, followed by the deposition of the conductive metal material 1030 on the exposed surfaces of the metal liner until the via and line openings are filled with the conductive metal material 1030. The metal liner can be formed using the same processes and materials as described above with reference to the metal liner of FIG. 10. Similarly, the conductive metal material 1030 can be deposited using the same processes and materials as described above with reference to the conductive metal material 1030 of FIG. 10. In some embodiments, the conductive metal material 1030 used to form the BSM layers 1050 and the conductive metal material 1030 used to form the backside inductor 1160 are the same materials. In other embodiments, the conductive metal material 1030 used to form the BSM layers 1050 and the conductive metal material 1030 used to form the backside inductor 1160 are different materials.

A planarization process may subsequently be performed to remove portions of the metal liner and the conductive metal material 1030 (collectively referred to as “overburden material”) that is present below the bottom surface of the layer of ILD material 1010 to form the via 1015-4 and the line 1120-1.

For simplicity sake, only the formation of a first inductor layer has been described. However, it should be understood that the formation of any number of additional inductor layers, including the vias 1115-1, 1115-2, 1115-3 and the lines 1120-2, 1120-3, 1120-4 as depicted in FIG. 11 may be formed utilizing the same processes and materials used to form the via 1015-4 and the line 1120-1 as described above. Following the formation of the inductor 1160, additional BSM layers may be formed depending on the particular requirements of the semicondcutor. For example, vias 1015-5, 1015-6 may additionally be formed using any generally known damascene processes to connect the inductor 1160 to one or more additional BSM layers.

As further depicted by assembly 1100 of FIG. 11, the inductor 1160 is integrated with the BSM layers 1050 and connected to the first BSM stack 1060, which in turn is interconnected to various components of the semiconductor device, e.g., connecting to the source/drain region 620-1 through electrical contact 925-1. The inductor 1160, and specifically the first inductor line (i.e., line 1120-1) of the inductor 1160, is vertically aligned with, and connected to the source/drain region 620-1 through the BSM stack 1060 and electrical contact 925-1.

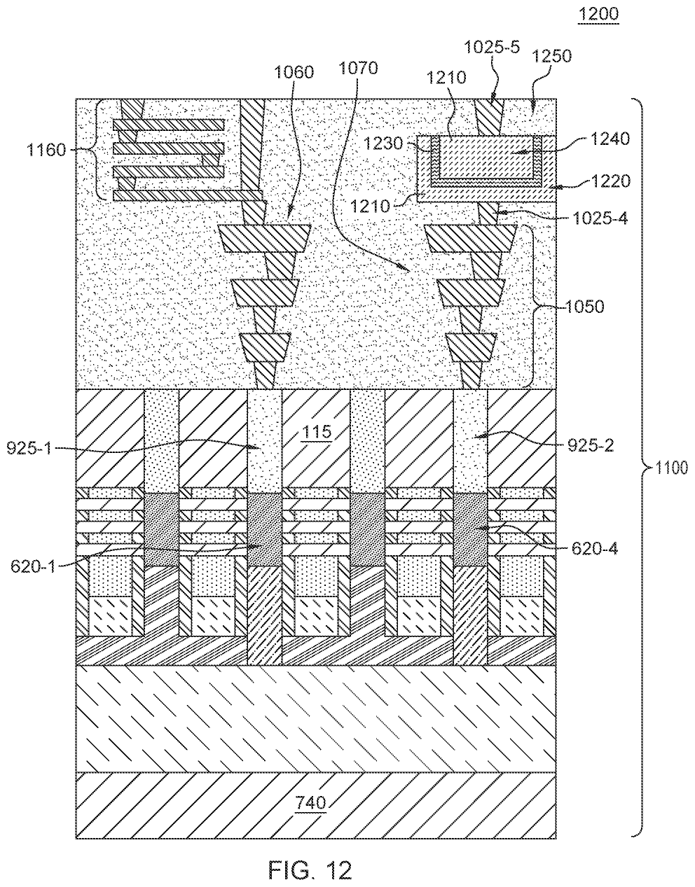

FIG. 12 illustrates exemplary FEOL processes for the formation of a backside capacitor 1250 that is arranged in parallel with the inductor 1160 and integrated with the BSM stack 1070. Although the processes for the formation of the capacitor 1250 are described herein as being subsequent to the processes for the formation of the inductor 1160, it should be appreciated that the processes for the formation of the capacitor 1250 may be performed prior to or simultaneously with the formation of the inductor 1160.

In the exemplary FEOL fabrication processes discussed below with respect to assembly 1200 of FIG. 12, the backside capacitor 1250 is formed from a first capacitor electrode 1210, a second capacitor electrode 1240, and a dielectric isolation layer 1230 interposed between the first and second capacitor electrodes 1220,1240. The capacitor 1250 is integrated with the BSM stack 1070, which in turn is interconnected to various components of the semiconductor device, e.g., connecting to the source/drain region 620-4 through the electrical contact 925-2.

In assembly of 1200 of FIG. 12, a via opening and a capacitor line opening (not depicted) are formed in one or more layers of the ILD material 1010. A first patterned hard mask (not depicted) is formed on the exposed surface of a layer of the ILD material 1010 such that the portion of the underlying layer(s) of the ILD material 1010 corresponding to the via opening to be formed is left exposed, while the remaining portions of the underlying structure of the layer(s) of the ILD material 1010 are protected by the patterned hard mask. The portion of the layer(s) of the ILD material 1010 left uncovered by the patterned hard mask is removed using an anisotropic etching process.

After the via opening is formed, another patterned hard mask (not depicted) is formed on the exposed surface of the layer of ILD material 1010 such that the portion of the underlying layer of ILD material 1010 corresponding to the line opening to be formed is left exposed, while the remaining portions of the underlying layer of the ILD material 1010 are protected by the patterned hard mask. The portions of the layer of the ILD material 1010 left uncovered by the patterned hard mask is similarly removed by an anisotropic etching process.

The conductive metal material 1030 is then deposited on the exposed surfaces of the patterned layer(s) of the ILD material 1010 until the via opening is filled with the conductive metal material 1030, thereby forming the via 1025-4. Then the conductive metal material 1210 is conformally deposited on the exposed surfaces of the patterned layer(s) of the ILD material 1010 and the via 1025-4 to form the first capacitor electrode 1220, followed by the conformal deposition of the dielectric isolation layer 1230, and then another conformal deposition of the conductive metal material 1210 on the exposed surfaces of the dielectric isolation layer 1230 (collectively referred to as “overburden material”) that is present below the bottom surface of the layer(s) of the ILD material 1010 to form the second capacitor electrode 1240.

The metal material 1210 can be deposited using the same processes and materials as described above with reference to the conductive metal material 1030 of FIG. 10. In some embodiments, the conductive metal material 1030 used to form the via 1025-4 and the conductive metal material 1210 used to form the first capacitor electrode 1120 and the second capacitor electrode 1240 are the same materials. In other embodiments, the conductive metal material 1030 used to form the via 1025-4 and the conductive metal material 1210 used to form the first capacitor electrode 1220 and the second capacitor electrode 1240 are different materials.

Following the formation of the inductor 1160 and the capacitor 1250, additional BSM layers may be formed depending on the particular requirements of the semicondcutor. For example, via 1025-5 may additionally be formed using any generally known damascene processes to connect the capacitor 1250 to one or more additional BSM layers.

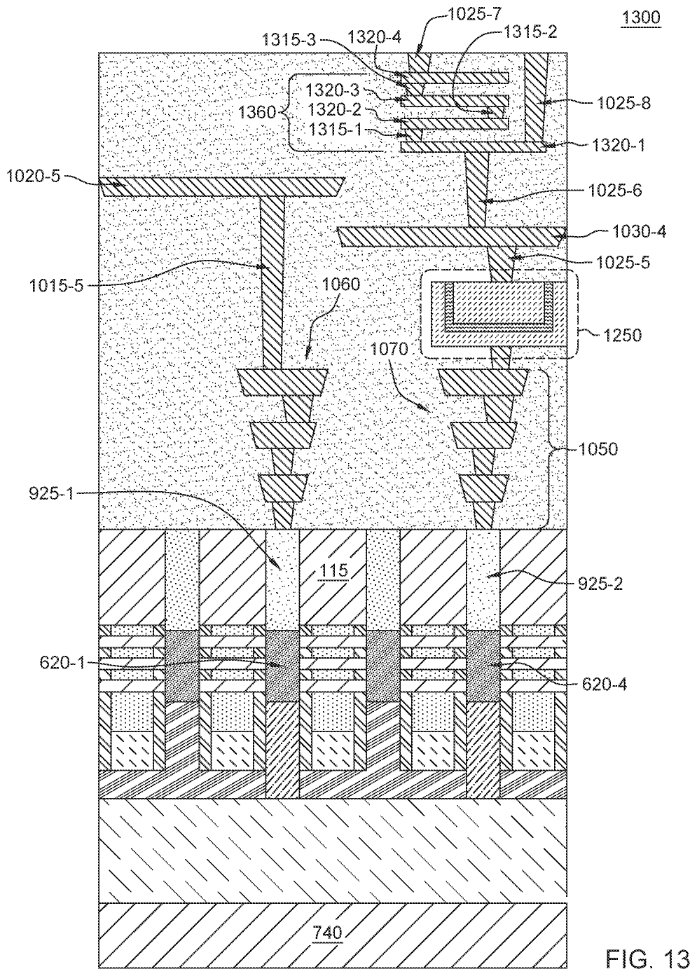

FIG. 13 illustrates exemplary FEOL processes for the formation of a backside capacitor 1250 and a backside capacitor 1360 that are arranged in series and integrated with the BSM stack 1050. It should be appreciated that although the backside inductor 1360 is depicted as being integrated with the BSM layers 1050 above the backside capacitor 1250, in other embodiments, the backside inductor 1360 may be integrated with the BSM layers 1050 below the backside capacitor and connected to the BSM stack 1070.

In assembly 1300, the capacitor 1250 may be formed utilizing the same processes and materials as described with reference to FIG. 12. One or more additional BSM metal layers, including line 1020-5 connected to via 1015-5, and vias 1025-5, 1025-6 and line 1030-4 separated by a plurality of layers of (ILD) material 1010 may be formed on top of the capacitor 1250 utilizing the same processes and materials as described with reference to FIG. 12. Then, the inductor 1360 may be formed utilizing the same processes and materials as described with reference to FIG. 11. The inductor 1360 includes a plurality of vias 1315-1, 1315-2, 1315-3 and a plurality of lines 1320-1, 1320-2, 1320-3, and 1320-4.

Following the formation of the capacitor 1250 and the inductor 1360, additional BSM layers may be formed depending on the particular requirements of the semiconductor. For example, vias 1025-7, 1025-8 may additionally be formed using any generally known damascene processes to connect the capacitor 1250 and the inductor 1360 to one or more additional BSM layers.

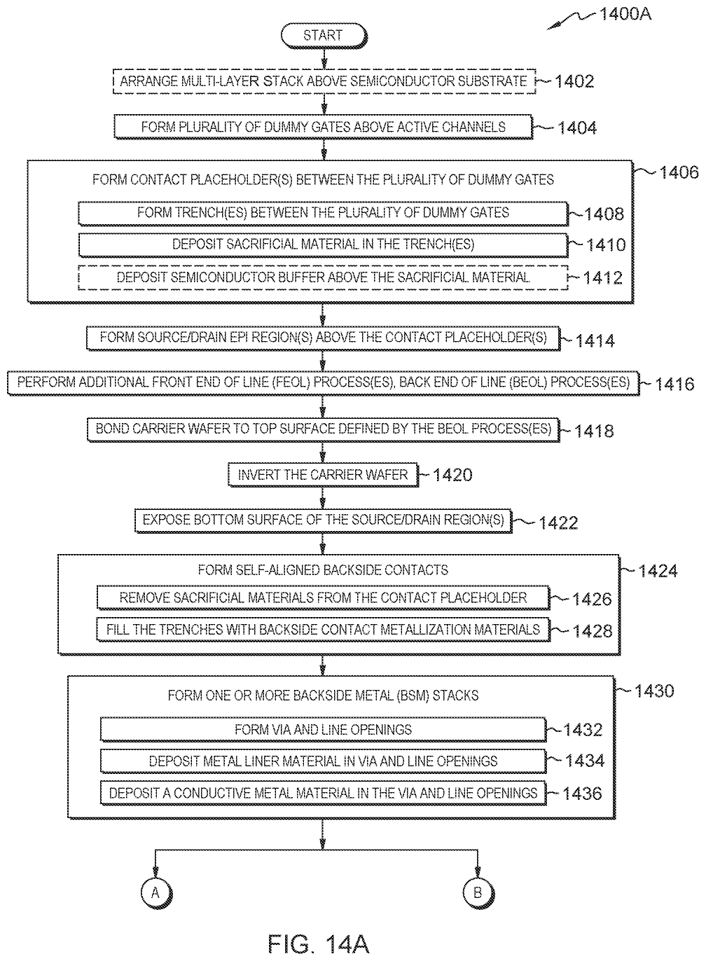

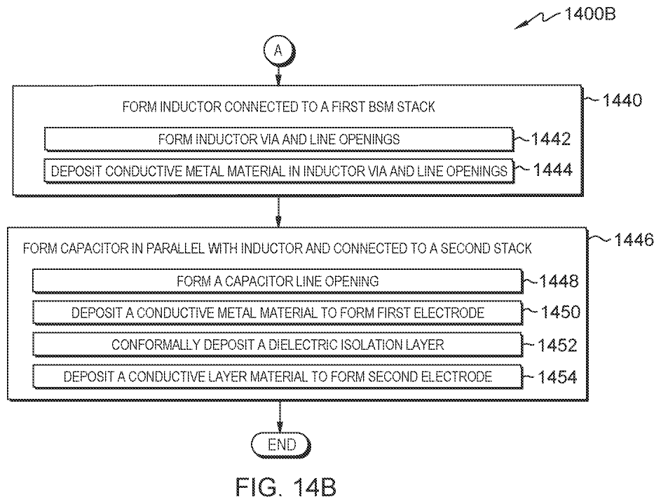

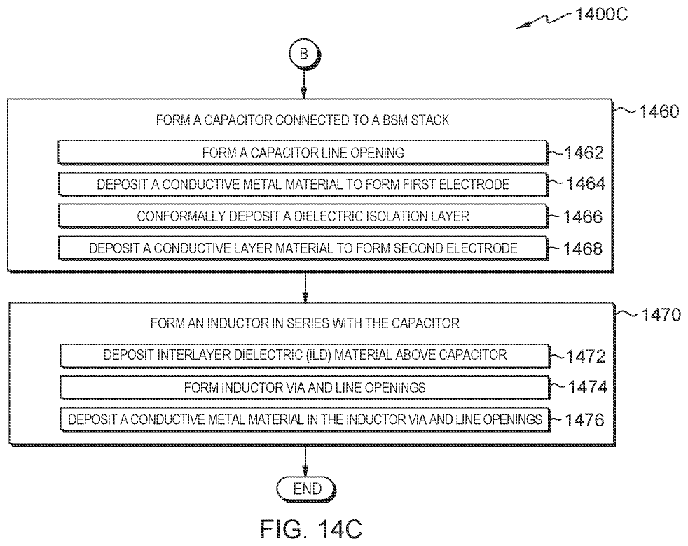

FIGS. 14A-14C, generally designated 1400A, 1400B, and 1400C, respectfully are a method of fabricating a semiconductor device. The method may be used in conjunction with other embodiments, for example, any of the exemplary fabrication sequences of FIGS. 1A, 2A, . . . , 9A, . . . , FIGS. 1B, 2B, . . . , 9B, and FIGS. 10-13.

The method optionally begins at block 1402, where a multi-layer stack is arranged above a semiconductor substrate. In some embodiments, the multi-layer stack comprises a nanosheet stack arranged above a dielectric isolation layer. In some embodiments, the nanosheet stack comprises an alternating arrangement of Si layers and SiGe layers. In some embodiments (e.g., as shown in FIG. 3A), the dielectric layer is formed of SiGe with any suitable atomic percentage of Ge. In other embodiments (e.g., as shown in FIG. 3B), the dielectric layer is formed of a BOX layer of a SOI wafer.

At block 1404, a plurality of dummy gates are formed above active channels. At block 1406, one or more contact placeholders are formed between the plurality of dummy gates. In some embodiments, forming the one or more contact placeholders comprises (at block 1408) forming one or more line openings between the plurality of dummy gates, (at block 1410) depositing sacrificial material in the one or more line openings, and (optionally, at block 1412) depositing a semiconductor buffer above the sacrificial material. In some embodiments, each of the dummy gates comprises gate material between gate spacers, and forming the one or more trenches comprises etching through the nanosheet stack between gate spacers of respective dummy gates.

At block 1414, one or more source/drain regions (epitaxy) are formed above the contact placeholders. For example, semiconductor material may be deposited in the one or more line openings to form the one or more source/drain regions. At block 1416, one or more additional front end of line (FEOL) processes are performed, and one or more back end of line (BEOL) processes are performed to the semiconductor device.

At block 1418, a carrier wafer is bonded to a top surface defined by the one or more BEOL processes. At block 1420, the carrier wafer is inverted. At block 1422, the bottom surface of the one or more source/drain regions are exposed (e.g., removing the contact placeholder(s)). At block 1424, one or more self-aligned backside electrical contacts are formed. In some embodiments, forming the one or more self-aligned backside electrical contacts comprises (at block 1426) removing sacrificial material from the one or more contact placeholders, and (at block 1428) filling the trenches resulting from the removal of the sacrificial material with a backside contact metallization material to form the one or more backside electrical contacts.

At block 1430, one or more backside metal (BSM) stacks that are connected to the one or more electrical contacts is formed. In some embodiments, forming the one or more BSM stacks comprises (at block 1432) forming one or more via and line openings in one or more layers of an interlayer dielectric (ILD) material, optionally depositing (at block 1434) a metal liner material in the one or more via and line openings, depositing (at block 1436) a conductive metal material in the via and line openings to form one or more vias and lines. In some embodiments, the one or more BSM stacks are in vertical alignment with, and connected to one or more source/drain regions through one or more electrical contacts.

In some embodiments, the method proceeds from block 1436 to path

“A” of FIG. 14B. Continuing from path “A” of FIG. 14B, at block 1440, an inductor connected to a first BSM stack is formed. In some embodiments, forming the inductor comprises (at block 1442) forming one or more inductor via and line openings in one or more layers of an interlayer dielectric (ILD) material above the first BSM stack, and depositing (at block 1444) a conductive metal material in the inductor via and line openings. In some embodiments, the inductor is in vertical alignment with, and connected to, a source/drain region through the BSM stack and a first electrical contact.

In some embodiments, at block 1446, a capacitor that is parallel to the inductor and connected to a second BSM stack is formed. In some embodiments, forming the capacitor that is parallel to the inductor comprises (at block 1448) forming a line opening in one or more layers of an interlayer dielectric (ILD) material above the second BSM stack, depositing (at block 1450) a conductive metal material to form a first capacitor electrode, conformally depositing (at block 1452) a dielectric isolation layer on the first capacitor electrode, and depositing (at block 1454) the conductive metal material on the dielectric isolation layer to form a second capacitor electrode.

In other embodiments, the method proceeds from block 1436 to path “B” of FIG. 14C. Continuing from path “B” of FIG. 14C, at block 1460, a capacitor connected to a BSM stack is formed. In some embodiments, forming the capacitor comprises (at block 1462) forming a line opening in one or more layers of an interlayer dielectric (ILD) material above the first BSM stack, depositing (at block 1464) a conductive metal material to form a first capacitor electrode, conformally depositing (at block 1466) a dielectric isolation layer on the first capacitor electrode, and depositing (at block 1468) the conductive metal material on the dielectric isolation layer to form a second capacitor electrode.

At block 1470, an inductor is formed in series with the capacitor. In some embodiments, forming the inductor comprises (at block 1472) depositing one or more additional layers of an interlayer dielectric (ILD) material on top of the capacitor, forming (at block 1474) one or more inductor via and line openings in the one or more layers of the ILD material above the capacitor, and depositing (at block 1476) a conductive metal material in the inductor via and line openings. In some embodiments, the inductor is in vertical alignment with, and connected to, a source/drain region through the capacitor, the first BSM stack, and the first electrical contact.

It should be appreciated that although the method steps 1460-1476 describe an inductor formed above a capacitor in series with one another, alternative method steps may similarly be applied to a capacitor formed above an inductor in series with one another.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure is not limited to specific described embodiments. Instead, any combination of the features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages discussed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

While the foregoing is directed to embodiments of the present invention, other and further embodiments of the invention may be devised without departing from the basic scope thereof, and the scope thereof is determined by the claims that follow.

What is claimed is:

1. A method comprising:
forming one or more backside metal (BSM) stacks in one or more layers of dielectric material, wherein the one or more BSM stacks are in contact with one or more backside electrical contacts located on a backside of a semiconductor substrate, and further wherein the one or more backside electrical contacts are in contact with one or more source/drain regions of a first device location on a front side of the semiconductor substrate; and
forming an inductor that is integrated with a first BSM stack of the one or more BSM stacks, wherein forming the inductor includes:
depositing one or more additional layers of the dielectric material on top of the one or more BSM stacks;
forming a plurality of inductor via and line openings in the one or more additional layers of the dielectric material; and
depositing a first conductive metal material in the plurality of inductor via and line openings.

2. The method of claim 1, wherein forming the one or more BSM stacks in the layer of dielectric material includes:
depositing the one or more layers of dielectric material on top of the one or more backside electrical contacts;
forming a plurality of BSM via and line openings in the one or more layers of dielectric material; and
depositing a second conductive metal material in the plurality of BSM via and line openings.

3. The method of claim 1, further comprising forming the one or more backside electrical contacts based, at least in part, on:
etching through a sacrificial material of the one or more electrical contact placeholders to form one or more electrical contact openings; and
depositing a third conductive metal material in the one or more electrical contact openings.

4. The method of claim 1, further comprising forming a capacitor that is in series with the inductor, wherein forming the capacitor includes:
depositing one or more additional layers of the dielectric material on top of the inductor;
etching the one or more additional layers of the dielectric material to form a capacitor opening above the inductor;
depositing a first layer of a conductive metal material in a first portion of the capacitor opening to form a first capacitor electrode;
depositing a dielectric isolation layer on the first layer of the conductive metal material; and
depositing a second layer of the conductive metal material on the dielectric isolation layer to form a second capacitor electrode.

5. The method of claim 1, further comprising forming a capacitor that is in parallel to the inductor, wherein forming the capacitor includes:
etching the one or more additional layers of the dielectric material above a second BSM stack to form a capacitor opening;
depositing a first layer of a conductive metal material in a first portion of the capacitor opening to form a first capacitor electrode;
depositing a dielectric isolation layer on the first layer of the conductive metal material; and
depositing a second layer of the conductive metal material in a second portion of the capacitor opening to form a second capacitor electrode.

6. A semiconductor device, comprising:
a first device located on a frontside of a semiconductor substrate;
an inductor located on a backside of the semiconductor substrate and integrated with a first backside metal (BSM) stack; and
a first electrical contact located between the frontside and the backside of the semiconductor substrate, wherein a first end of the first electrical contact is connected to the first BSM stack and a second end of the first electrical contact is connected to a first source/drain region of the first device.

7. The semiconductor device of claim 6, wherein the first device is a transistor.

8. The semiconductor device of claim 6, wherein a connection between the inductor and the first BSM stack is in vertical alignment with the first source/drain region of the first device.

9. The semiconductor device of claim 6, further comprising:
a second device located on the frontside of the semiconductor substrate;
a capacitor located on the backside of the semiconductor substrate and integrated with a second backside metal (BSM) stack; and
a second electrical contact located between the frontside and the frontside and the backside of the semiconductor substrate, wherein a first end of the second electrical contact is connected to the second BSM stack and a second end of the second electrical contact is connected to a second source/drain region of the second device.

10. The semiconductor device of claim 9, wherein the second device is a transistor.

11. The semiconductor device of claim 9, wherein the capacitor includes a dielectric isolation layer located between a first capacitor electrode and a second capacitor electrode.

12. The semiconductor device of claim 9, wherein the capacitor and the inductor are arranged in parallel.

13. The semiconductor device of claim 9, wherein a connection between the capacitor and the second BSM stack is in vertical alignment the second source/drain region of the second device.

14. A semiconductor device, comprising:
a device located on a frontside of a semiconductor substrate;
a capacitor located on a backside of the semiconductor substrate and integrated with a backside metal (BSM) stack; and
a first electrical contact located between the frontside and the backside of the semiconductor substrate, wherein a first end of the first electrical contact is connected to the BSM stack and a second end of the first electrical contact is connected to a source/drain region of the device.

15. The semiconductor device of claim 14, wherein the device is a transistor.

16. The semiconductor device of claim 14, wherein a connection between the capacitor and the BSM stack is in vertical alignment with the source/drain region of the device.

17. The semiconductor device of claim 14, further comprising:
an inductor located on the backside of the semiconductor substrate and integrated with the BSM stack, wherein a first end of the second electrical contact is connected to the BSM stack and a second end of the second electrical contact is connected to the source/drain region of the device.

18. The semiconductor device of claim 17, wherein a connection between the inductor and the BSM stack is in vertical alignment with the source/drain region of the device.

19. The semiconductor device of claim 17, wherein the inductor and the capacitor are arranged in series.

20. The semiconductor device of claim 17, wherein the inductor is integrated with the BSM stack either below or above the capacitor.
